(19) United States
(12) Patent Application Publication
(10) Pub. No.: US 2019/0334124 A1
(43) Pub. Date: Oct. 31, 2019

(54) OLED PACKAGING STRUCTURE AND OLED DISPLAY PANEL

(71) Applicant: Wuhan China Star Optoelectronics Semiconductor Display Technology Co., Ltd., Wuhan, Hubei (CN)

(72) Inventor: Zhewei PENG, Wuhan, Hubei (CN)

(21) Appl. No.: 16/087,651

(22) PCT Filed: Aug. 7, 2018
(86) PCT No.: PCT/CN2018/099133

§ 371 Date: Sep. 23, 2018

(30) Foreign Application Priority Data
Apr. 28, 2018 (CN) 201810399005.4

(51) Int. Cl. H01L 51/52; H01L 27/32

(52) U.S. Cl. CPC H01L 51/5259; H01L 2251/303; H01L 51/5246; H01L 27/3244

(57) ABSTRACT

An organic light emitting diode (OLED) packaging structure and an OLED display device are described. The OLED packaging structure includes a packaging substrate and a drying layer disposed on a surface of the packaging substrate and used to absorb water and oxygen gas. A fabricating material of the drying layer is a metal organic framework compound containing zinc, and the metal organic framework compound containing zinc is a porous structure.

### FIELD OF DISCLOSURE

The present disclosure relates to a technical field of displays, and more particularly to an OLED (organic light emitting diode) packaging structure and an OLED display panel.

### BACKGROUND OF DISCLOSURE

Organic light emitting diodes (OLEDs) have advantages of self-luminescence, low driving voltage, high luminous efficiency, and have broad application prospects in the display market. Different from conventional display technology, OLED display devices do not require a background light source, and different colors of light, can be obtained by applying a voltage to different organic material coatings.

Organic light emitting materials can easily react with water and oxygen, resulting in deactivation of the materials. Therefore, requirements for OLED display panels are as follows: lower than 10⁻⁶g/m²/day water vapor transmission rate. It is very important to maintain usage life of the OLED display panels by improving structure used to block water and oxygen of the OLED display panel for isolating it from water and oxygen. Therefore, there is an urgent need for an OLED packaging structure and an OLED display panel to solve the blocking issues of the OLED display panel against water and oxygen.

### SUMMARY OF DISCLOSURE

The present disclosure provides an OLED (organic light emitting diode) packaging structure and an OLED display device to solve a problem that the inorganic materials are used in the conventional OLED display panel to absorb the internal water of an OLED display panel, resulting in an increase in a thickness of the OLED packaging structure and the OLED display panel,

To achieve the above object, a technical solution provided by the present disclosure is as follows:

According to an aspect of the present disclosure, an OLED packaging structure is provided and includes: a packaging substrate and a drying layer disposed on a surface of the packaging substrate and used to absorb water and oxygen gas;

wherein a fabrication material of the drying layer is a metal organic framework compound containing zinc, the metal organic framework compound containing zinc is a porous structure, and a chemical formula of the metal organic framework compound containing zinc is ZnO₄(BDC)₃.

According to a preferred embodiment of the present disclosure, a specific surface area of the metal organic framework compound containing zinc is between 2900 m²/g and 3362 m²/g.

According to a preferred embodiment of the present disclosure, the metal organic framework compound containing zinc is formed by coordination bonding of a zinc ion with an organic ligand para-dicarboxylic acid.

According to a preferred embodiment of the present disclosure, the packaging substrate is a glass substrate, a side portion around the glass substrate is a protrusion portion, wherein the drying layer is disposed on a surface of the glass substrate, and the protrusion portion surrounds the drying layer.

According to another aspect of the present disclosure, an OLED display panel is provided and includes:
a thin film transistor substrate;
an OLED light-emitting layer disposed on a surface of the thin film transistor substrate;
an OLED packaging structure disposed above the OLED light-emitting layer, wherein the OLEO packaging structure and the thin film transistor substrate form a closed chamber, so as to protect the OLED light-emitting layer;
a frame-sealing adhesive disposed on an edge region of the thin film transistor substrate to glue the thin, film transistor substrate to the OLED packaging structure; and
wherein the OLED packaging structure comprises:
   a packaging substrate; and
   a drying layer disposed on a surface of the packaging substrate and used to absorb water and oxygen gas, wherein the drying layer is disposed on a surface of the packaging structure to which the light-emitting layer is adjacent;
wherein a fabricating material of the drying layer is a metal organic framework compound containing zinc, the metal organic framework compound containing zinc is a porous structure.

According to a preferred embodiment of the present disclosure, a specific surface area of the metal organic framework compound containing zinc is between 2900 m²/g and 3362 m²/g.

According to a preferred embodiment of the present disclosure, the metal organic framework compound containing zinc is formed by coordination bonding of a zinc ion with an organic ligand para-dicarboxylic acid.

According to a preferred embodiment of the present disclosure, a chemical formula of the metal organic framework compound containing zinc is ZnO₄(BDC)₃.

According to a preferred embodiment of the present disclosure, the packaging substrate is a glass substrate, a side portion around the glass substrate is a protrusion portion, the drying layer is disposed on a surface of the glass substrate, and the protrusion portion surrounds the drying layer, wherein the protrusion portion is glued to the thin film transistor substrate by the frame-sealing adhesive.

According to a further aspect of the present disclosure, an OLEO packaging structure is provided and includes:
a packaging substrate; and
a drying layer disposed on a surface of the packaging substrate and used to absorb water and oxygen gas;
wherein a fabricating material of the drying layer is a metal organic framework compound containing zinc, and the metal organic framework compound containing zinc is a porous structure.

According to a preferred embodiment of the present disclosure, a specific surface area of the metal organic framework compound containing zinc is between 2900 m²/g and 3362 m²/g.

According to a preferred embodiment of the present disclosure, the metal organic framework compound containing zinc is formed by coordination bonding of a zinc ion with an organic ligand para-dicarboxylic acid.

According to a preferred embodiment of the present disclosure, the packaging substrate is a glass substrate, a side portion around the glass substrate is a protrusion portion, wherein the drying layer is disposed on a surface of the glass substrate, and the protrusion portion surrounds the drying layer.

An advantage of the present disclosure is that: an OLED packaging structure and an OLED display panel are provided. Under a premise of ensuring the water absorption effect of the drying layer, by setting a preparation material of the drying layer in a packaging structure to be a metal organic framework compound containing zinc, a thickness of the drying layer is reduced, thereby reducing a thickness of the OLED packaging structure and the OLED display panel, for ensuring an uniformity of the film layer of the organic electroluminescent device and improving the display efficiency of the screen.

### DESCRIPTION OF DRAWINGS

In order to more clearly describe embodiments of the present disclosure or technical solutions in a conventional technology, drawings required to be used for the embodiments or descriptions of the conventional technology are simply described hereinafter. Apparently, the drawings described below only illustrate some embodiments of the present disclosure. Those skilled in the art can obtain other drawings based on these drawings disclosed herein without creative effort.

FIG. 1 is a structural schematic diagram of an OLED (organic light emitting diode) display panel in conventional technology.

FIG. 2 is a structural schematic diagram of an OLED packaging structure in an embodiment of the present disclosure.

FIG. 3 is a structural schematic diagram of an OLED display panel in an embodiment of the present disclosure.

### DETAILED DESCRIPTION OF PREFERRED EMBODIMENTS

The following description of the embodiments with reference to the appended drawings is used for illustrating specific embodiments which may be used for carrying out the present disclosure. The directional terms described by the present disclosure, such as “upper”, “lower”, “front”, “back”, “left”, “right”, “inner”, “outer”, “side”, etc. are only directions by referring to the accompanying drawings. Thus, the used directional terms are used to describe and understand the present disclosure, but the present disclosure, is not limited thereto. In figures, elements with similar structures are indicated with the same numbers.

The present disclosure provides an OLED (organic light emitting diode) packaging structure and an OLED display panel for the problem that the inorganic material is used to absorb internal water of the OLED display panel in conventional OLED display panels, resulting in, an increase in thickness of the OLED packaging structure and the OLED display panel. The present embodiment can improve the defect.

The following further describes the present disclosure with reference to the accompanying drawings and specific embodiments.

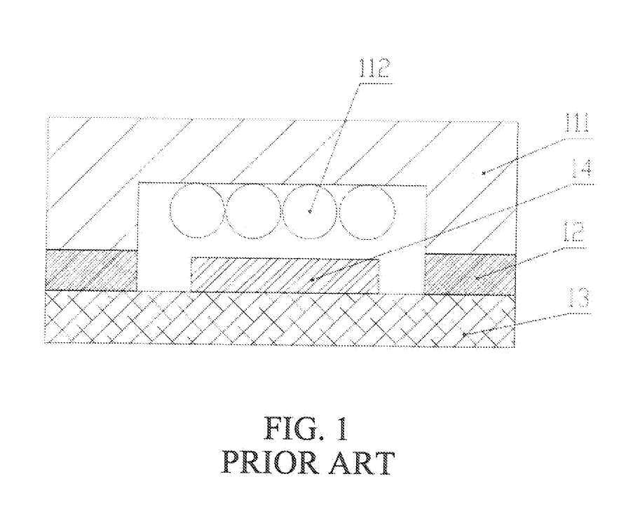

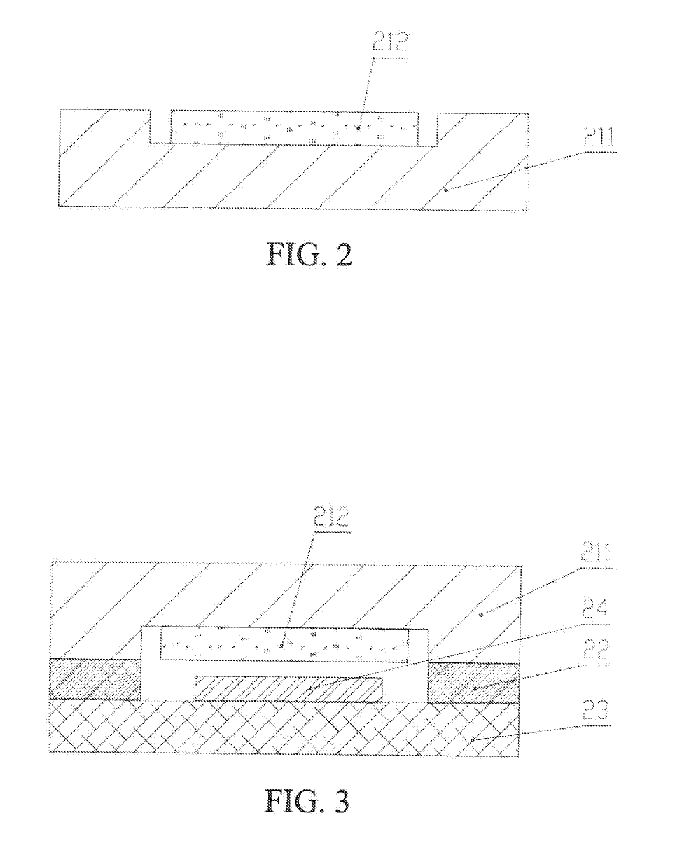

FIG. 1 and FIG. 2 are structural schematic diagrams of an OLED display panel in embodiments of the present disclosure. FIG. 3 is a structural schematic diagram of an OLED display panel in an embodiment of the present disclosure.

As shown in FIG. 2, the present disclosure provides an OLED packaging structure. The OLED packaging structure includes a packaging substrate 211 and a drying layer 212 disposed on a surface of the packaging substrate and used to absorb water and oxygen gas;

wherein a fabrication material of the drying layer 212 is a metal organic framework compound containing zinc (referred to as Zn-MOF), the metal organic framework compound containing zinc (Zn-MOF) is a porous structure.

It is explained that the metal organic framework compound containing zinc (Zn-MOF) in the present disclosure is a novel porous material, and the metal organic framework compound containing zinc (Zn-MOF) has an extremely large specific surface area, and thus the drying layer 212 made of this material can provide a contact surface greater than a contact surface of an inorganic material for contacting with water, thereby absorbing the water.

Further, a specific surface area of the metal organic framework compound containing zinc (Zn-MOF) is between 2900 m²/g and 3362 m²/g.

Preferably, the metal organic framework compound containing zinc (Zn-MOF) is formed by coordination bonding of a zinc ion with an organic ligand 1,4-dicarboxybenzene (referred to as H₂BDC), so as to form a framework material with a large specific surface area and a regular pore structure.

A chemical formula of the metal organic framework compound containing zinc (Zn-MOF) is ZnO₄(BDC)₃, which can generate weak chemical forces (such as van der Waals forces, hydrogen bonds, etc.) between water molecules so as to trap water. Compared to conventional solid desiccants, the porous metal organic framework compound containing zinc (Zn-MOF) can provide a relatively great contact area with water, even a small amount of the metal organic framework compound containing zinc (Zn-MOF) can achieve the same water absorption effect as the conventional desiccant, thereby reducing the amount of desiccant in the packaging structure and reducing the thickness of the packaging structure.

Preferably, the packaging substrate 211 is a glass substrate. A side portion around the glass substrate is a protrusion portion, wherein the drying layer 212 is disposed on a surface of the glass substrate, and the protrusion portion surrounding the drying layer being equivalent to a capping structure of the packaging substrate 211. The drying layer is attached to a middle area of an inner surface of the capping.

FIG. 1 illustrates a moisture-proof manner of an OLEO display panel in another embodiment of the present disclosure. An inorganic moisture-proof material 112 (e.g., calcium oxide, barium oxide, etc.) is attached to the cover plate 111. Then, a cover plate 111 is sealed, using a sealant 12, with a thin film transistor substrate 13, on which the OLED light emitting layer 24 is vapor-deposited. Because such structure can block water and oxygen gas of an external environment, internal water can also be adsorbed by the inorganic material 112, thereby improving the using life of the OLED display panel. However, the structure of the inorganic moisture-proof material 112 significantly increases the thickness of the display device, which is far from a current thin and light area of the display panel. Therefore, in the present disclosure, the metal organic framework compound containing zinc is selected to be a main structural preparation material of the OLED drying layer.

According to another aspect of the present disclosure, as shown in FIG. 3, an OLED display panel is further provided. The OLED display panel includes:
a thin film transistor substrate 23, which usually includes a substrate and an thin film transistor array disposed over the substrate;
an OLED light-emitting layer 24 disposed on a surface of the thin film transistor substrate; where usually, the OLED light-emitting layer 24 includes a light-emitting device, but since damage of water and oxygen gas on the light-emitting device is especially great, a packaging structure is needed to protect the light-emitting device from water and oxygen gas. The drying layer of the present disclosure is used to absorb the water in the environment where the light emitting device is located, so as, to protect the emitting device;
an OLED packaging structure 21 disposed above the OLED light-emitting layer, wherein the OLED packaging structure 21 and the thin film transistor substrate 23a form a closed chamber, so as to protect the OLED light-emitting layer. It can be understood that other structures may also exist between the OLED light emitting layer and the packaging structure 21, such as a TFE layer (thin film encapsulation layer) a touch layer, a polarizer, and the like on the OLED light emitting layer;
a frame-sealing adhesive 22 disposed on an edge region of the thin film transistor substrate 23 and used to align and glue the edge region of the thin film transistor substrate 23 to an edge region of the packaging substrate 211, so as to glue the thin film transistor substrate to the OLED packaging structure;
where the OLED packaging structure 21 includes a packaging substrate 212; and a drying layer 212 disposed on a surface of the packaging substrate 211 and used to absorb water and oxygen gas, wherein the drying layer 212 is disposed on a surface of the packaging structure to which the light-emitting layer 23 is adjacent;
wherein a fabricating material of the drying layer 212 is a metal organic framework compound containing zinc, the metal organic framework compound containing zinc is a porous structure.

Specifically, a specific surface area of the metal organic framework compound containing zinc is between 2900 m²/g and 3362 m²/g.

Preferably, the metal organic framework compound containing zinc is formed by coordination bonding of a zinc ion with an organic ligand para-dicarboxylic acid.

Preferably, a chemical formula of the metal organic framework compound containing zinc is ZnO₄(BDC)_{3.}

Preferably, the packaging substrate 211 is a glass substrate, a side portion around the glass substrate is a protrusion portion (not shown), the drying layer 212 is disposed on a surface of the glass substrate and surrounded by the protrusion portion (not shown), wherein the protrusion portion is glued to the thin film transistor substrate 23 by the frame-sealing adhesive 22.

Since a principle of the OLED display panel in the present disclosure is the same as a working principle of the OLED packaging structure, the principle of the OLED display panel specifically refers to the working principle of the OLED packaging structure, which is not repeated here.

An advantage of the present disclosure is that an OLED packaging structure and an OLED display panel are provided. Under a premise of ensuring the water absorption effect of the drying layer, by setting a preparation material of the drying layer in a packaging structure to be a metal organic framework compound containing zinc, a thickness of the drying layer is reduced, thereby reducing a thickness of the OLED packaging structure and the OLED display panel, for ensuring an uniformity of the film layer of the organic electroluminescent device and improving the display efficiency of the screen.

As described above, although the present disclosure has been described in preferred embodiments, they are not intended to limit the disclosure. One of ordinary skill in the art, without departing from the spirit and scope of the disclosure within, can make various modifications and variations, so the range of the scope of the disclosure is defined by the claims.

1. An organic light emitting diode (OLED) packaging structure, comprising:
a packaging substrate; and
a drying layer disposed on a surface of the packaging substrate and used to absorb water and oxygen gas;
wherein a fabrication material of the drying layer is a metal organic framework compound containing zinc, the metal organic framework compound containing zinc is a porous structure, and a chemical formula of the metal organic framework compound containing zinc is ZnO₄(BDC)₃.

2. The OLED packaging structure according to claim 1, wherein a specific surface area of the metal organic framework compound containing zinc is between 2900 m²/g and 3362 m²/g.

3. The OLED packaging structure according to claim 1, wherein the metal organic framework compound containing zinc is formed by coordination bonding of a zinc ion with an organic ligand para-dicarboxylic acid.

4. The OLED packaging structure according to claim 1, wherein the packaging substrate is a glass substrate, a side portion around the glass substrate is a protrusion portion, wherein the drying layer is disposed on a surface of the glass substrate, and the protrusion portion surrounds the drying layer.

5. An organic light emitting diode (OLED) display panel, comprising a thin film transistor substrate;
an OLED light-emitting layer disposed on a surface of the thin film transistor substrate;
an OLED packaging structure disposed above the OLED light-emitting layer, wherein the OLED packaging structure and the thin film transistor substrate form a closed chamber, so as to protect the OLED light-emitting layer;
a frame-sealing adhesive disposed on an edge region of the thin film transistor substrate to glue the thin film transistor substrate to the OLED packaging structure; and
wherein the OLED packaging structure comprises:
a packaging substrate; and
a drying layer disposed on a surface of the packaging substrate and used to absorb water and oxygen gas, wherein the drying layer is disposed on a surface of the packaging structure to which the light-emitting layer is adjacent;
wherein a fabricating material of the drying layer is a metal organic framework compound containing zinc, the metal organic framework compound containing zinc is a porous structure.

6. The OLED packaging structure according to claim 5, wherein a specific surface area of the metal organic framework compound containing zinc is between 2900 m²/g and 3362 m²/g.

7. The OLED packaging structure according to claim 5, wherein the metal organic framework compound containing zinc is formed by coordination bonding of a zinc ion with an organic ligand para-dicarboxylic acid.

8. The OLED packaging structure according to claim 5, wherein a chemical formula of the metal organic framework compound containing zinc is ZnO₄(BDC)_{3.}

9. The OLED packaging structure according to claim 5, wherein the packaging substrate is a glass substrate, a side portion around the glass substrate is a protrusion portion, the drying layer is disposed on a surface of the glass substrate, and the protrusion portion surrounds the drying layer, wherein the protrusion portion is glued to the thin film transistor substrate by the frame-sealing adhesive.

10. An organic light emitting diode (OLED) packaging structure, comprising:
a packaging substrate; and
a drying layer disposed on a surface of the packaging substrate and used to absorb water and oxygen gas;
wherein a fabricating material of the drying layer is a metal organic framework compound containing zinc, and the metal organic framework compound containing zinc is a porous structure.

11. The OLED packaging structure according to claim 10, wherein a specific surface area of the metal organic framework compound containing zinc is between 2900 m²/g and 3362 m²/g.

12. The OLED packaging structure according to claim 10, wherein the metal organic framework compound containing zinc is formed by coordination bonding of a zinc ion with an organic ligand para-dicarboxylic acid.

13. The OLED packaging structure according to claim 10, wherein the packaging substrate is a glass substrate, a side portion around the glass substrate is a protrusion portion, wherein the drying layer is disposed on a surface of the glass substrate, and the protrusion portion surrounds the drying layer.
